(19) United States
(12) Patent Application Publication
(10) Pub. No.: US 2010/0180933 A1
(43) Pub. Date: Jul. 22, 2010

(54) GROUNDING SYSTEM AND METHOD FOR USE WITH SOLAR PANEL MODULES

(75) Inventors: Jeffrey M. Aftanas, Ortonville, MI (US); Donald L. Munoz, Bloomfield Hills, MI (US)

Correspondence Address: HARNESS, DICKEY & PIERCE, P.L.C., P.O. BOX 828, BLOOMFIELD HILLS, MI, 48303, US

(73) Assignee: JAC Products, Inc., Saline, MI (US)

(21) Appl. No.: 12/689,614

(22) Filed: Jan. 19, 2010

Related U.S. Application Data
(60) Provisional application No. 61/145,663, filed on Jan. 19, 2009.

(51) Int. Cl. H01L 31/048

(52) U.S. Cl. 136/251

(57) ABSTRACT

A grounding system for a solar panel system having a plurality of solar panel cells. The system may have an electrically conductive first frame section adapted to be secured to a first solar panel module having a first channel, the first frame section also having a hole that opens into the first channel. An electrically conductive second frame section is adapted to be secured to a second solar panel module which has a second channel, the second frame section also having a hole that opens into the second channel. An electrically conductive grounding splice member is positioned in the first and second channels. A pair of electrically conductive fasteners is disposed in the holes of the first and second frame sections and engages the electrically conductive grounding splice member, to electrically and mechanically couple the first and second frame sections together.

### CROSS REFERENCE TO RELATED APPLICATIONS

The present application claims priority from U.S. Provisional patent application Ser. No. 61/145,663, filed Jan. 19, 2009, the disclosure of which is hereby incorporated by reference in its entirety into the present disclosure.

### FIELD

The present disclosure relates to frames for solar panel modules, and more particularly to frames for solar panel modules that incorporate a provision for grounding the frames of adjacently positioned modules together.

### BACKGROUND

The statements in this section merely provide background information related to the present disclosure and may not constitute prior art.

In solar panel applications each solar panel cell is designated as a “module” and typically supported within an aluminum frame. When a plurality of modules are positioned adjacent one another a solar panel “array” is formed.

Each module of a solar panel array must be grounded. When a plurality of modules is used to form an array, grounding is typically accomplished by using a single electrical cable and stringing the electrical cable along the full length of all the modules of the array. The cable is physically and electrically coupled to the frame of each module, typically with some type of external J-hook that is affixed to an outer surface of a portion of the frame of each module. The cable itself is a heavy gauge cable, typically on the order of 6-8 AWG, and typically made of solid copper. As will be appreciated, then, cost of the grounding electrical cabling alone can represent a significant cost in the installation of a solar panel system. In large scale applications where hundreds or even thousands of modules are used to form one or more arrays, a large quantity of electrical cabling will be required to ground all of the modules. The total length of the electrical cabling required for such large installations can be hundreds or even thousands of meters.

The requirement for using heavy gauge electrical cabling to ground all of the modules of a solar panel array also significantly adds to the work and time required to install a solar panel system. When such a system is installed on a roof of a residence or building, the cabling must be carried by a worker up to the roof of the residence or building. Since the cabling is typically 6-8 gauge (AWG) cabling, the weight of the cabling can be significant. The time required to lay the cabling out along the modules of the solar panel array and to fasten it to the frame of every module in the array can also be time consuming for the installer. This can significantly add to the overall installation cost of a solar panel system.

### SUMMARY

In one aspect the present application is directed to a grounding system for a solar panel system having a plurality of solar panel cells. The system may have an electrically conductive first frame section adapted to be secured to a first solar panel module having a first channel, the first frame section also having a hole that opens into the first channel. An electrically conductive second frame section is adapted to be secured to a second solar panel module which has a second channel, the second frame section also having a hole that opens into the second channel. An electrically conductive grounding splice member is positioned in the first and second channels. A pair of electrically conductive fasteners is disposed in the holes of the first and second frame sections and engages the electrically conductive grounding splice member, to electrically and mechanically couple the first and second frame sections together.

In another aspect the present disclosure is directed to a grounding system for a solar panel system having a plurality of solar panel cells. The system may comprise an electrically conductive first frame section adapted to be secured to a first solar panel module having a first channel, with the first frame section also having a hole that opens into the first channel. An electrically conductive second frame section is adapted to be secured to a second solar panel module and has a second channel, with the second frame section also having a hole that opens into the second channel. An electrically conductive bar is positioned in the first and second channels and has dimensions that approximate a cross sectional dimension of the first and second channels. A pair of electrically conductive fasteners is disposed in the holes of the first and second frame sections and engages the electrically conductive bar to wedge the electrically conductive bar in the channels. This electrically and mechanically couples the first and second frame sections together.

In still another aspect the present disclosure relates to a grounding system for a solar panel system having a plurality of solar panel cells. The system may comprise an electrically conductive first frame section adapted to be secured to a first solar panel module having a first channel, with the first frame section also having a hole adjacent the first channel. An electrically conductive second frame section is adapted to be secured to a second solar panel module and has a second channel, with the second frame section also having a hole adjacent the second channel. An electrically conductive bar is positioned in the first and second channels. A pair of electrically conductive straps are secured to the frame sections for clamping the electrically conductive bar to the frame sections and forming an electrically conductive path between the frame sections.

### BRIEF DESCRIPTION OF THE DRAWINGS

The drawings described herein are for illustration purposes only and are not intended to limit the scope of the present disclosure in any way.

FIG. 1 is a perspective view of a grounding system in accordance with a first embodiment of the present disclosure;

FIG. 2 is a perspective view of a grounding system in accordance with a second embodiment of the present disclosure;

FIG. 3A is a perspective view of a third embodiment of a grounding system in accordance with the present disclosure;

FIG. 3B is a rear perspective view of a portion of one of the frames shown in FIG. 3A;

FIG. 4 is a perspective view of a fourth embodiment of the grounding system of the present disclosure;

FIG. 5 is a perspective view of a fifth embodiment of the grounding system of the present disclosure; and

FIG. 6 is a perspective view of a sixth embodiment of the grounding system of the present disclosure.

### DETAILED DESCRIPTION

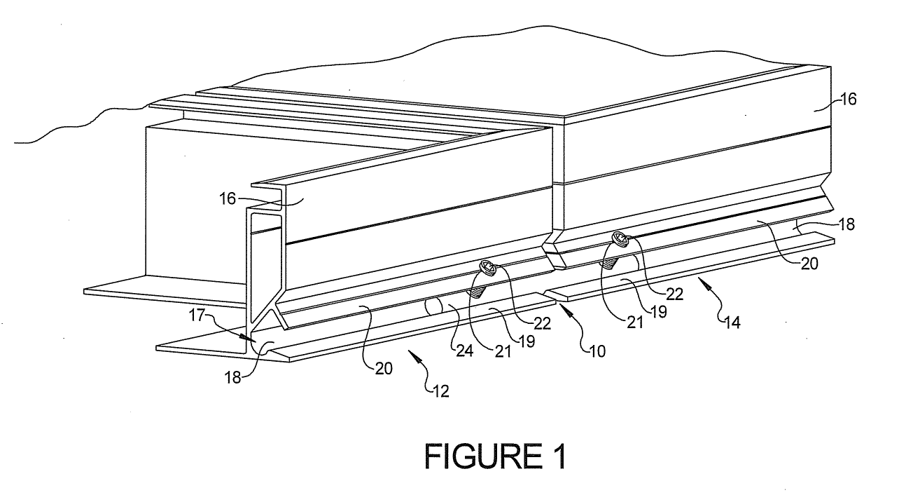

Referring to FIG. 1, there is shown portions of a pair of solar panel modules 12 and 14 physically and electrically coupled together by a grounding system 10 in accordance with one embodiment of the present disclosure. While only two solar panel modules 12 and 14 are shown, it will be appreciated that in many applications a larger plurality of solar panel modules, perhaps dozens, hundreds or even thousands, may be coupled together to form a larger solar panel array.

Each solar panel module 12 includes a frame 16, which typically is made from aluminum. The active components of each module are shown in phantom and denoted by reference numerals 15. The frames 16 are extruded aluminum components that have an integrally formed channel 17 having a semi-circular cross-sectional surface 18, an outwardly projecting lower lip 19 and an outwardly projecting flange 20.

The ground system 10 may comprise a threaded hole 21 in each flange 20, a pair of threaded set screws 22 and an electrically conductive grounding splice member 24, such as a rod or bar, that has dimensions enabling it to be inserted into the channels 17 of each frame 16, either from an end of one of the channels, or possibly in from the sides of the frames 16, provided the dimensions of the grounding splice member 24 permit it to be inserted through the gap between the lower lip 19 and the flange 20. The grounding splice member 24 may have a circular or semicircular cross sectional shape with a cross sectional dimension that approximates a cross sectional dimension of the channels 17 so that it is able to rest in the semi-circular portions 18 of the channels 17. The grounding member 24 may be made of aluminum or any other electrically conductive material, but aluminum will likely be preferred in most applications because it will not rust when exposed to the elements. The set screws 22 are tightened to clamp the grounding splice member 24 in the channels 17 of the two frames 16. When the grounding splice member 24 is clamped to both frames 16 it forms a conductive path that electrically couples the frames 16 together. The grounding splice member 24 also helps to provide significant structural rigidity to the interconnected modules 12. While not shown in the drawings, it will be appreciated that a relatively short length of grounding cable will typically be attached to one of the frames 16 and will lead to a ground spike driven into the earth to provide a path to ground for electrical current that flows through the frames 16 and the ground splice member(s) 24.

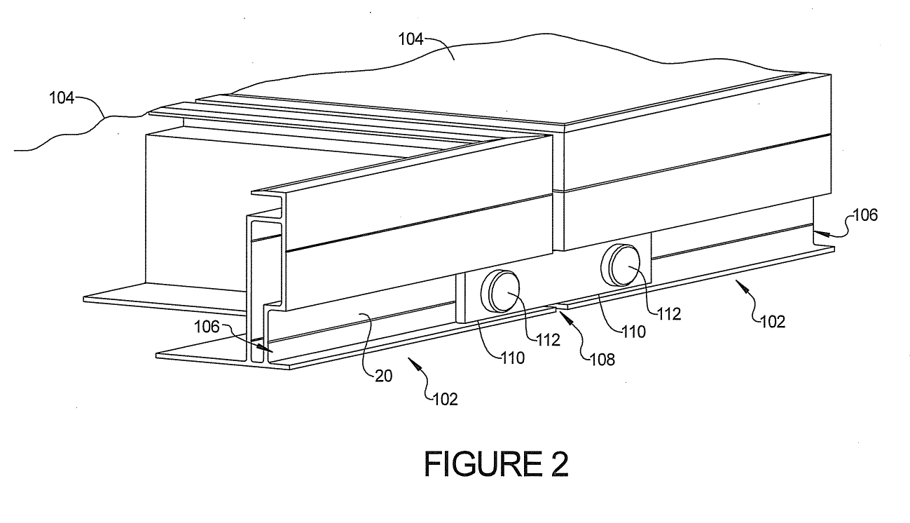

Referring to FIG. 2, a grounding system 100 is shown in accordance with another embodiment of the present disclosure. In this example a pair of solar panel frames 102 are used to position two solar panel modules 104, shown in phantom, adjacent one another. The frames 102 are preferably extruded aluminum frames that each include an outwardly opening U-shaped channel 106. An electrically conductive member, preferably in the form of a non-ferrous metal plate 108 with high electrical conductivity properties, is dimensioned to fit in the channels 106. The plate 108 has two openings 110, preferably shaped as elongated slots, that receive threaded fasteners 112. The fasteners 112 extend into threaded holes that are hidden from view in FIG. 2, but are behind the plate 108. The slot-like shape of the openings 110 in the plate 108 provide a small degree of lateral and angular adjustability of the plate 108 to ease installation of the fasteners 112 into their respective threaded holes and over uneven mating surfaces. The plate 108 thus forms an electrically conductive member that electrically couples the frames 102 together and also provides structural rigidity to the interconnected frames.

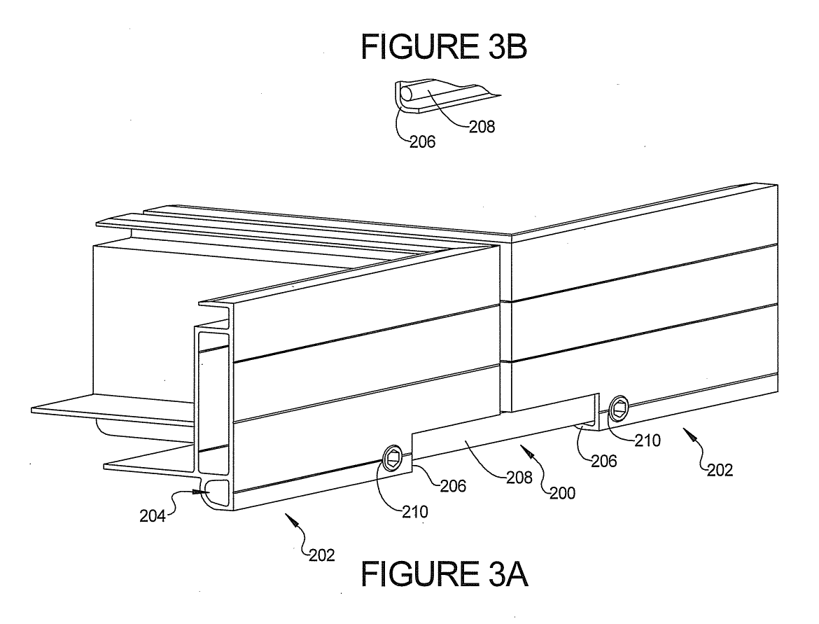

Referring to FIG. 3A, a grounding system 200 in accordance with another embodiment of the present disclosure is shown. Solar panel frames 202 each include an extruded, completely closed channel 204 with a notched out section 206 at the corner of each. A metallic element, for example an aluminum rod 208, is inserted into the channels 204. Threaded holes 210 are formed adjacent each notched out section 206. Threaded set screws 212 are threadably inserted into the holes 210 and clamp the rod 208 in the channels 204. The rod 208 is preferably of a length that extends just greater than the spacing between threaded holes 210 when the two frames 202 are positioned adjacent one another. The backside of the cutout section 206 of one frame 202 is shown in FIG. 3B. The rod 208 also provides significant structural rigidity to the assembly of frames 202 once they are mechanically and electrically coupled together. Thus, the grounding system 200 may be viewed as comprising the channels 204, the holes 210, the set screws 212 and the rod 208.

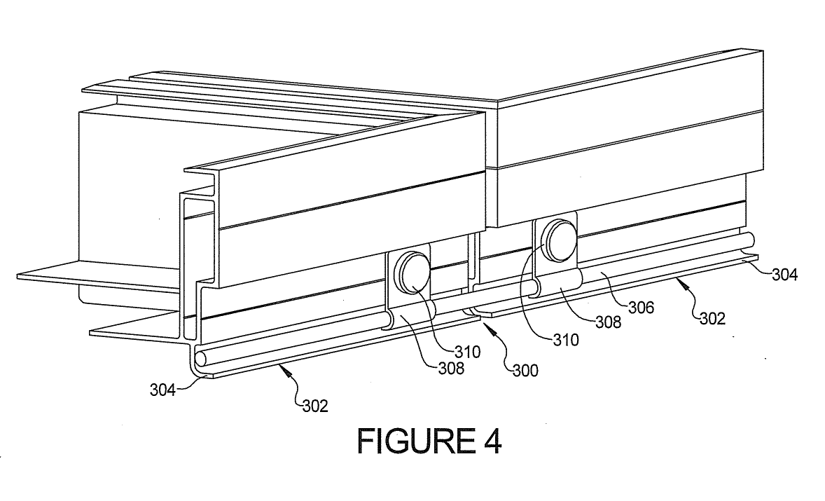

Referring to FIG. 4, a grounding system 300 in accordance with another embodiment of the present disclosure is shown. Grounding system 300 makes use of solar panel frames 302 that each include an extruded, curved lip 304. An electrically conductive rod, for example an aluminum rod 306, is held against the lips 304 of adjacently positioned frames 302 by a pair of hooks 308. Hooks 308 are also preferably made from aluminum so as to be conductive. Hooks 308 are secured via threaded fasteners 310 that engage in threaded holes (not visible) in the frames 302. The rod 306 has a length that is just slightly longer than the spacing between holes that engage the threaded fasteners 310. Thus, the system 300 may be viewed as the lips 304 of each frame 302, the rod 306, the hooks 308 and the fasteners 310.

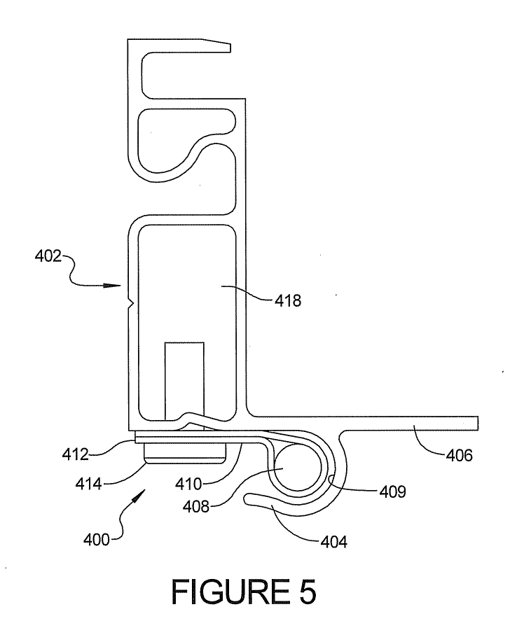

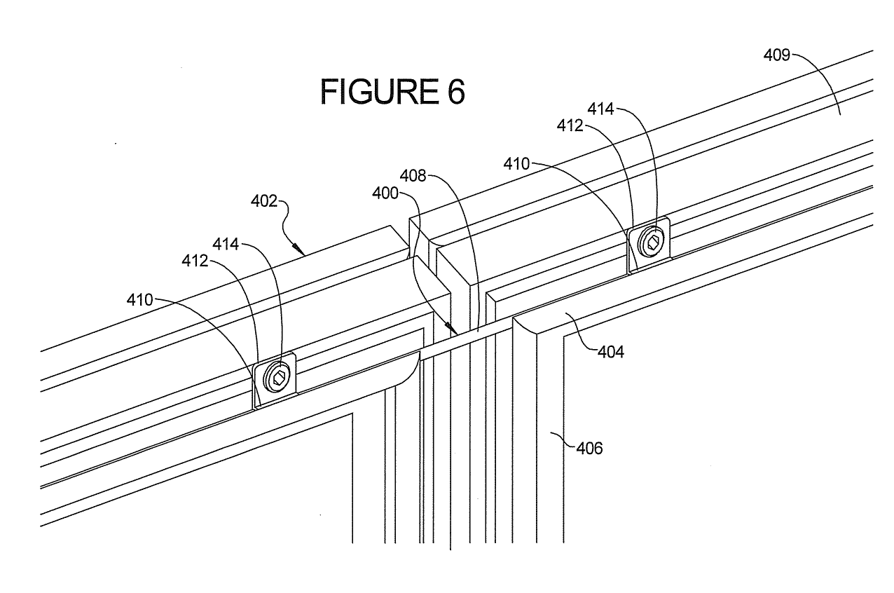

Referring to FIGS. 5 and 6, a grounding system 400 in accordance with another embodiment of the present disclosure is shown. FIG. 5 shows an end view of one frame 402, although it will be appreciated that two of such frames 402 will be positioned adjacent to one another, as shown in FIG. 6, when attaching the components of the grounding system 400.

As shown in FIG. 5, Each frame 402 forms an extruded aluminum component having a curving lip 404 on its undersurface 406. An elongated rod, for example an aluminum rod 408, is positioned within a channel 409 formed by the lip 404 and is held in the channel by an aluminum strap 410. The aluminum strap 410 wraps around the rod 408, and a free end 412 of the strap 410 has holes formed in it to permit a threaded fastener 414 to be inserted therethrough. The threaded fastener 414 extends through a threaded hole 416 in the undersurface 406 of the frame 402 into an interior channel 418 formed in the frame 402. In FIG. 6 a pair of the threaded fasteners 414 are shown securing the rod 408 to the two frames 402. The grounding system 400 may be thought of as including the rod 408, the straps 410 and the threaded fasteners 414.

In each of the disclosed embodiments, the frames may be formed so that all four sides of the frames are extruded with the same shape. In this manner, the installer does not have to pay attention to placing one particular side of the solar panel frame so that one specific side is accessible to permit installing the grounding system. The various embodiments also make it fast and easy for a technician or installer to uncouple the individual modules, in the event the solar panel array needs to be disassembled and removed from a residence or building. The various embodiments disclosed herein enable a plurality of frames of independent solar panel cells to be electrically and mechanically coupled together more quickly than with conventional cabling. A particular advantage is that the various embodiments described herein do not require the use of any special tools; conventional screwdrivers and/or nut drivers may be used to assemble the various components to the frame sections. Still another advantage is that the various embodiments eliminate the need for the installer to carry large and heavy amounts of heavy gauge electrical cabling to a work site, as well as up on to the roof of a residence or commercial building. Accordingly, the various embodiments may significantly reduce the overall time that is required in coupling a plurality of solar panel cells together for proper grounding.

While various embodiments have been described, those skilled in the art will recognize modifications or variations which might be made without departing from the present disclosure. The examples illustrate the various embodiments and are not intended to limit the present disclosure. Therefore, the description and claims should be interpreted liberally with only such limitation as is necessary in view of the pertinent prior art.

What is claimed is:

1. A grounding system for a solar panel system having a plurality of solar panel cells, the system comprising:
an electrically conductive first frame section adapted to be secured to a first solar panel module having a first channel, the first frame section also having a hole that opens into the first channel;
an electrically conductive second frame section adapted to be secured to a second solar panel module and having a second channel, the second frame section also having a hole that opens into the second channel;
an electrically conductive grounding splice member positioned in the first and second channels; and
a pair of electrically conductive fasteners disposed in the holes of the first and second frame sections, and engaging the electrically conductive grounding splice member, to electrically and mechanically couple the first and second frame sections together.

2. The grounding system of claim 1, wherein the electrically conductive grounding splice member comprises a generally circular, elongated, solid bar, and wherein the fasteners clamp the generally circular, elongated, solid bar within the channels.

3. The grounding system of claim 1, wherein the electrically conductive grounding splice member comprises a rectangular plate, and the channels each comprise U-shaped channels, and wherein the fasteners clamp the rectangular plate within the U-shaped channels.

4. The grounding system of claim 1, wherein the channel comprises an opening along its full length.

5. The grounding system of claim 1, wherein the channels each form a completely closed, round channel.

6. The grounding system of claim 1, wherein each of the first and second frame sections include a cutout portion adjacent a distal edge thereof.

7. The grounding system of claim 1, wherein each of the frame sections include an outwardly projecting flange that helps to define its respective said channel.

8. The grounding system of claim 7, wherein each said electrically conductive fastening implement comprises a threaded set screw that wedges a portion of the electrically conductive splice member into its associated said channel.

9. The grounding system of claim 8, wherein the holes are formed in the outwardly projecting flanges of the frame sections, and wherein the set screws extend through the holes to wedge the electrically conductive splice member in the channels.

10. A grounding system for a solar panel system having a plurality of solar panel cells, the system comprising:
an electrically conductive first frame section adapted to be secured to a first solar panel module having a first channel, the first frame section also having a hole that opens into the first channel;
an electrically conductive second frame section adapted to be secured to a second solar panel module and having a second channel, the second frame section also having a hole that opens into the second channel;
an electrically conductive bar positioned in the first and second channels and having dimensions that approximate a cross sectional dimension of the first and second channels; and
a pair of electrically conductive fasteners disposed in the holes of the first and second frame sections, and engaging the electrically conductive bar to wedge the electrically conductive bar in the channels, to electrically and mechanically couple the first and second frame sections together.

11. The grounding system of claim 10, wherein:
each of the channels comprises a U-shaped channel; and
the electrically conductive bar comprises a generally rectangular shape that has dimensions approximating those of the U-shaped channels.

12. The grounding system of claim 10, wherein:
each of the channels comprises an at least a semicircular shape; and
the electrically conductive bar comprises a generally circular shape that has dimensions approximating those of the U-shaped channels.

13. The grounding system of claim 10, wherein the pair of electrically conductive fasteners comprise set screws.

14. A grounding system for a solar panel system having a plurality of solar panel cells, the system comprising:
an electrically conductive first frame section adapted to be secured to a first solar panel module having a first channel, the first frame section also having a hole adjacent the first channel;
an electrically conductive second frame section adapted to be secured to a second solar panel module and having a second channel, the second frame section also having a hole adjacent the second channel;
an electrically conductive bar positioned in the first and second channels; and
a pair of electrically conductive straps secured to the frame sections for clamping the electrically conductive bar to the frame sections and forming an electrically conductive path between the frame sections.

15. The grounding system of claim 14, wherein the first and second channels form semicircular channels.

16. The grounding system of claim 14, wherein the electrically conductive straps each wrap partially around the electrically conductive bar.

17. The grounding system of claim 14, wherein the electrically conductive straps wrap completely around the electrically conductive bar.

18. The grounding system of claim 14, wherein the electrically conductive bar comprises a circular, elongated bar.

19. The grounding system of claim 14, further comprising:
a pair of threaded fastening elements;
a threaded opening formed in each said frame section;
holes formed in each of the electrically conductive straps; and
the threaded fastening elements extending through the holes in the electrically conductive straps and into the threaded holes in the frame sections to secure the electrically conductive bar in the channels of the frame sections.

20. The grounding system of claim 19, wherein the frame sections each include a hollow interior area, and wherein the threaded fastening elements extend into the threaded fastening area of each of the frame sections.
